(19) United States
(12) Patent Application Publication
(10) Pub. No.: US 2025/0070754 A1
(43) Pub. Date: Feb. 27, 2025

(54) FILTER USING TRANSVERSELY-EXCITED FILM BULK ACOUSTIC RESONATORS

(71) Applicant: Murata Manufacturing Co., Ltd., Nagaokakyo-shi (JP)

(72) Inventors: Luke Myers, Santa Barbara, CA (US); Wei Yang, Goleta, CA (US); Andrew Guyette, San Mateo, CA (US); Greg Dyer, Santa Barbara, CA (US)

(21) Appl. No.: 18/940,507

(22) Filed: Nov. 7, 2024

Related U.S. Application Data
(63) Continuation of application No. 17/722,344, filed on Apr. 17, 2022.
(60) Provisional application No. 63/175,933, filed on Apr. 16, 2021.

(51) Int. Cl. H03H 9/60; H03H 9/13; H03H 9/205

(52) U.S. Cl. CPC H03H 9/605; H03H 9/13; H03H 9/205

(57) ABSTRACT

A bandpass filter is provided that includes a ladder filter circuit with at least one shunt transversely-excited film bulk acoustic resonators (XBAR) and at least one series XBAR. Each of the XBARs includes a diaphragm having an LN-equivalent thickness greater than or equal to 360 nm, and each of the XBARs includes a diaphragm having an LN-equivalent thickness less than or equal to 375 nm.

### CROSS REFERENCE TO RELATED APPLICATIONS

This application is a continuation of U.S. patent application Ser. No. 17/722,344, filed Apr. 17, 2022, which claims priority from U.S. Provisional Patent Application No. 63/175,933, titled XBAR FILTERS FOR 5 GHZ WI-FI, filed Apr. 16, 2021, the entire contents of each of which are hereby incorporated by reference.

### TECHNICAL FIELD

This disclosure relates to radio frequency filters using acoustic wave resonators, and specifically to filters for use in communications equipment.

### BACKGROUND

A radio frequency (RF) filter is a two-port device configured to pass some frequencies and to stop other frequencies, where “pass” means transmit with relatively low signal loss and “stop” means block or substantially attenuate. The range of frequencies passed by a filter is referred to as the “pass-band” of the filter. The range of frequencies stopped by such a filter is referred to as the “stop-band” of the filter. A typical RF filter has at least one pass-band and at least one stop-band. Specific requirements on a pass-band or stop-band depend on the specific application. For example, a “pass-band” may be defined as a frequency range where the insertion loss of a filter is better than a defined value such as 1 dB, 2 dB, or 3 dB. A “stop-band” may be defined as a frequency range where the rejection of a filter is greater than a defined value such as 20 dB, 30 dB, 40 dB, or greater depending on application.

RF filters are used in communications systems where information is transmitted over wireless links. For example, RF filters may be found in the RF front-ends of cellular base stations, mobile telephone and computing devices, satellite transceivers and ground stations, IoT (Internet of Things) devices, laptop computers and tablets, fixed point radio links, and other communications systems. RF filters are also used in radar and electronic and information warfare systems.

RF filters typically require many design trade-offs to achieve, for each specific application, the best compromise between performance parameters such as insertion loss, rejection, isolation, power handling, linearity, size and cost. Specific design and manufacturing methods and enhancements can benefit simultaneously one or several of these requirements.

Performance enhancements to the RF filters in a wireless system can have broad impact to system performance. Improvements in RF filters can be leveraged to provide system performance improvements such as larger cell size, longer battery life, higher data rates, greater network capacity, lower cost, enhanced security, higher reliability, etc. These improvements can be realized at many levels of the wireless system both separately and in combination, for example at the RF module, RF transceiver, mobile or fixed sub-system, or network levels.

High performance RF filters for present communication systems commonly incorporate acoustic wave resonators including surface acoustic wave (SAW) resonators, bulk acoustic wave (BAW) resonators, film bulk acoustic wave resonators (FBAR), and other types of acoustic resonators. However, these existing technologies are not well-suited for use at the higher frequencies and bandwidths proposed for future communications networks.

The desire for wider communication channel bandwidths will inevitably lead to the use of higher frequency communications bands. Radio access technology for mobile telephone networks has been standardized by the 3GPP (3rd Generation Partnership Project). Radio access technology for 5th generation mobile networks is defined in the 5G NR (new radio) standard. The 5G NR standard defines several new communications bands. Two of these new communications bands are n77, which uses the frequency range from 3300 MHz to 4200 MHZ, and n79, which uses the frequency range from 4400 MHz to 5000 MHz. Both band n77 and band n79 use time-division duplexing (TDD), such that a communications device operating in band n77 and/or band n79 uses the same frequencies for both uplink and downlink transmissions. Bandpass filters for bands n77 and n79 must be capable of handling the transmit power of the communications device. Wi-Fi™ bands at 5 GHz and 6 GHz also require high frequency and wide bandwidth. The 5G NR standard also defines millimeter wave communication bands with frequencies between 24.25 GHz and 40 GHz.

The Transversely-Excited Film Bulk Acoustic Resonator (XBAR) is an acoustic resonator structure for use in microwave filters. The XBAR is described in U.S. Pat. No. 10,491,291, titled TRANSVERSELY EXCITED FILM BULK ACOUSTIC RESONATOR. An XBAR resonator comprises an interdigital transducer (IDT) at least partially disposed on a thin floating layer, or diaphragm which is or includes a layer of a single-crystal piezoelectric material. The IDT includes a first set of parallel fingers, extending from a first busbar and a second set of parallel fingers extending from a second busbar. The first and second sets of parallel fingers are interleaved. A microwave signal applied to the IDT excites a shear primary acoustic wave in the piezoelectric diaphragm. XBAR resonators provide very high electromechanical coupling and high frequency capability. XBAR resonators may be used in a variety of RF filters including band-reject filters, band-pass filters, duplexers, and multiplexers. XBARs are well suited for use in filters for communications bands with frequencies above 3 GHz.

### BRIEF DESCRIPTION OF THE DRAWINGS

FIG. 1 is a schematic diagram of an exemplary band-pass filter.

FIG. 2 has a schematic plan view and two schematic cross-sectional views of a transversely-excited film bulk acoustic resonator (XBAR).

FIG. 3 is an expanded schematic cross-sectional view of a portion of the XBAR of FIG. 2.

FIG. 4 is a graphic illustrating a shear primary acoustic mode in an XBAR.

FIG. 5 is a graph of the resonance frequency of an XBAR as a function of piezoelectric plate thickness for four different dielectric thicknesses.

FIG. 6 is a graph of the resonance frequency of an XBAR as a function of equivalent diaphragm thickness for four different dielectric thicknesses.

FIG. 7 is a graph of the anti-resonance frequency of an XBAR as a function of piezoelectric plate thickness for four different dielectric thicknesses.

FIG. 8 is a graph of the anti-resonance frequency of an XBAR as a function of equivalent diaphragm thickness for four different dielectric thicknesses.

FIG. 9 is a schematic diagram of an exemplary band-pass filter for 5 GHz Wi-Fi.

FIG. 10 is a graph of the magnitude of the input/output transfer function S21 for the exemplary band-pass filter of FIG. 9.

FIG. 11 is a flow chart of a process for fabricating an XBAR or a filter incorporating XBARs.

Throughout this description, elements appearing in figures are assigned three-digit or four-digit reference designators, where the two least significant digits are specific to the element and the one or two most significant digit is the figure number where the element is first introduced. An element that is not described in conjunction with a figure may be presumed to have the same characteristics and function as a previously-described element having the same reference designator.

### DETAILED DESCRIPTION

### Description of Apparatus

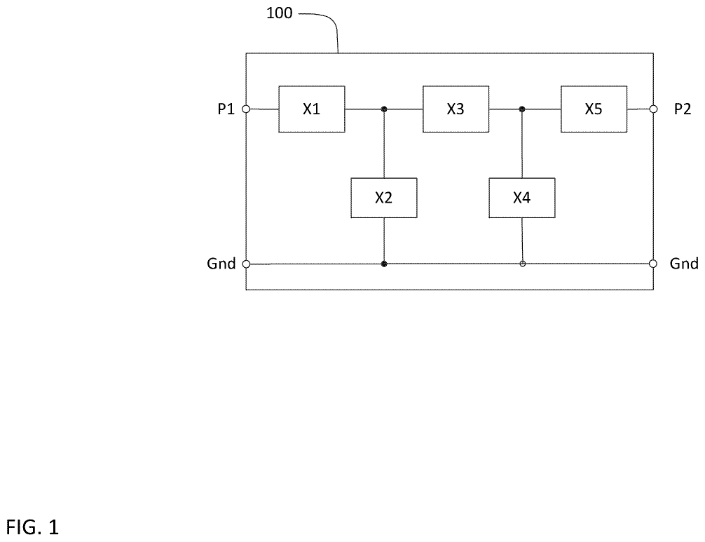

FIG. 1 is a schematic circuit diagram of an exemplary band-pass filter 100 using five XBARs X1-X5. The filter 100 may be, for example, a band-pass filter for use in a communication device. The filter 100 has a conventional ladder filter architecture including three series resonators X1, X3, X5 and two shunt resonators X2, X4. The three series resonators X1, X3, X5 are connected in series between a first port P1 and a second port P2. The filter 100 is bidirectional and either port may serve as the input or output of the filter. The two shunt resonators X2, X4 are connected from nodes between the series resonators to ground. All the shunt resonators and series resonators may be XBARs.

Each of the resonators X1 to X5 has a resonance frequency and an anti-resonance frequency. In over-simplified terms, each resonator is effectively a short circuit at its resonance frequency and effectively an open circuit at its anti-resonance frequency. Each resonator X1 to X5 creates a “transmission zero”, where the transmission between the input and output ports is very low. Note that the transmission at a “transmission zero” is not actually zero due to energy leakage through parasitic components and other effects. The three series resonators X1, X3, X5 create transmission zeros at their respective anti-resonance frequencies (where each resonator is effectively an open circuit). The two shunt resonators X2, X4 create transmission zeros at their respective resonance frequencies (where each resonator is effectively a short circuit). In a typical band-pass filter using acoustic resonators, resonance frequencies of the shunt resonators are positioned below the passband of the filter and the anti-resonance frequencies of the shunt resonators are within the passband. Resonance frequencies of the series resonators are within the passband and the anti-resonance frequencies of the series resonators are positioned above the passband.

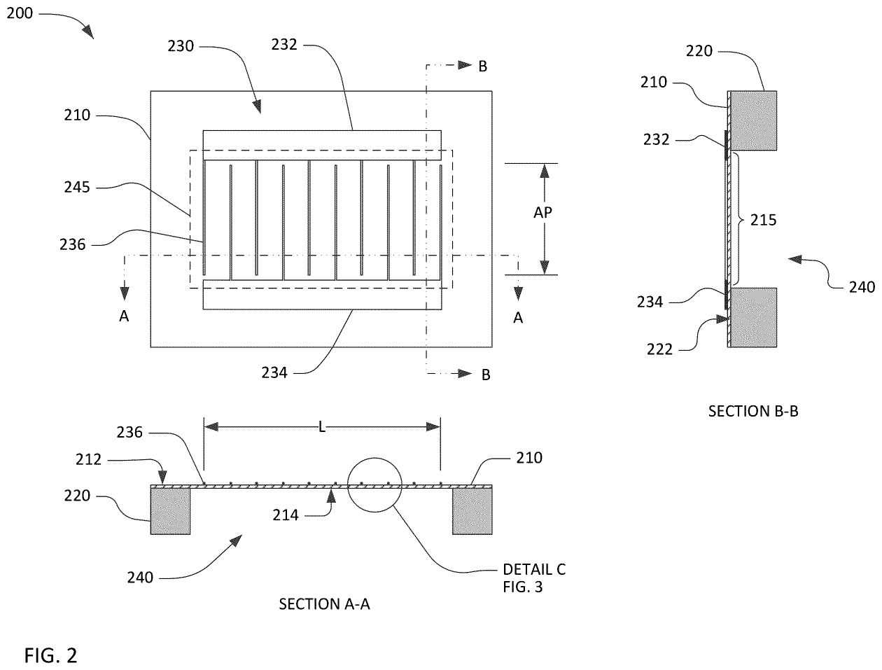

Referring now to FIG. 2, the structure of XBARs will be described in further detail. FIG. 2 shows a simplified schematic top view and orthogonal cross-sectional views of a an XBAR 200. The XBAR 200 is made up of a thin film conductor pattern formed on a surface of a piezoelectric plate 210 having a front surface 212 and a back surface 214. The front and back surfaces are essentially parallel. “Essentially parallel” means parallel to the extent possible within normal manufacturing tolerances. The piezoelectric plate is a thin single-crystal layer of a piezoelectric material such as lithium niobate, lithium tantalate, lanthanum gallium silicate, gallium nitride, or aluminum nitride. The piezoelectric plate is cut such that the orientation of the X, Y, and Z crystalline axes with respect to the front and back surfaces is known and consistent. In the examples presented in this patent, the piezoelectric plates are rotated YX-cut. However, XBARs may be fabricated on piezoelectric plates with other crystallographic orientations including rotated Z-cut and rotated Z-cut.

The back surface 214 of the piezoelectric plate 210 is attached to a surface 222 of the substrate 220 except for a portion of the piezoelectric plate 210 that forms a diaphragm 215 spanning a cavity 240 formed in the substrate 220. The cavity 240 has a perimeter defined by the intersection of the cavity and the surface 222 of the substrate 220. The portion of the piezoelectric plate that spans the cavity is referred to herein as the “diaphragm” due to its physical resemblance to the diaphragm of a microphone. As shown in FIG. 2, the diaphragm 215 is contiguous with the rest of the piezoelectric plate 210 around all of the perimeter 245 of the cavity 240. In this context, “contiguous” means “continuously connected without any intervening item”.

The substrate 220 provides mechanical support to the piezoelectric plate 210. The substrate 220 may be, for example, silicon, sapphire, quartz, or some other material or combination of materials. The back surface 214 of the piezoelectric plate 210 may be attached to the substrate 220 using a wafer bonding process. Alternatively, the piezoelectric plate 210 may be grown on the substrate 220 or otherwise attached to the substrate. The piezoelectric plate 210 may be attached directly to the substrate or may be attached to the substrate 220 via one or more intermediate material layers.

The cavity 240 is an empty space within a solid body of the resonator 200. The cavity 240 may be a hole completely through the substrate 220 (as shown in Section A-A and Section B-B) or a recess in the substrate 220 (not shown) that extends down from the diaphragm 215 into but not all the way through the substrate 220. The cavity 240 may be formed, for example, by selective etching of the substrate 220 before or after the piezoelectric plate 210 and the substrate 220 are attached.

The conductor pattern of the XBAR 200 includes an interdigital transducer (IDT) 230. An IDT is an electrode structure for converting between electrical and acoustic energy in piezoelectric devices. The IDT 230 includes a first plurality of parallel elongated conductors, commonly called “fingers”, such as finger 236, extending from a first busbar 232. The IDT 230 includes a second plurality of fingers extending from a second busbar 234. The first and second pluralities of parallel fingers are interleaved. The interleaved fingers overlap for a distance AP, commonly referred to as the “aperture” of the IDT. The center-to-center distance L between the outermost fingers of the IDT 230 is the “length” of the IDT.

The term “busbar” refers to the conductors that interconnect the first and second sets of fingers in an IDT. As shown in FIG. 2, each busbar 232, 234 is an elongated rectangular conductor with a long axis orthogonal to the interleaved fingers and having a length approximately equal to the length L of the IDT. The busbars of an IDT need not be rectangular or orthogonal to the interleaved fingers and may have lengths longer than the length of the IDT.

The first and second busbars 232, 234 serve as the terminals of the XBAR 200. A radio frequency or microwave signal applied between the two busbars 232, 234 of the IDT 230 excites a primary acoustic mode within the piezoelectric plate 210. As will be discussed in further detail, the primary acoustic mode is a bulk shear mode where acoustic energy propagates along a direction substantially orthogonal to the surface of the piezoelectric plate 210, which is also normal, or transverse, to the direction of the electric field created by the IDT fingers. Thus, the XBAR is considered a transversely-excited film bulk wave resonator.

The IDT 230 is positioned on the piezoelectric plate 210 such that at least a substantial portion of the fingers of the IDT 230 are disposed on the diaphragm 215 of the piezoelectric plate that spans, or is suspended over, the cavity 240. As shown in FIG. 2, the cavity 240 has a rectangular shape with an extent greater than the aperture AP and length L of the IDT 230. A cavity of an XBAR may have a different shape, such as a regular or irregular polygon. The cavity of an XBAR may have more or fewer than four sides, which may be straight or curved.

For ease of presentation in FIG. 2, the geometric pitch and width of the IDT fingers is greatly exaggerated with respect to the length (dimension L) and aperture (dimension AP) of the XBAR. An XBAR for a 5G device will have more than ten parallel fingers in the IDT 210. An XBAR may have hundreds, possibly thousands, of parallel fingers in the IDT 210. Similarly, the thickness of the fingers in the cross-sectional views is greatly exaggerated in the drawings.

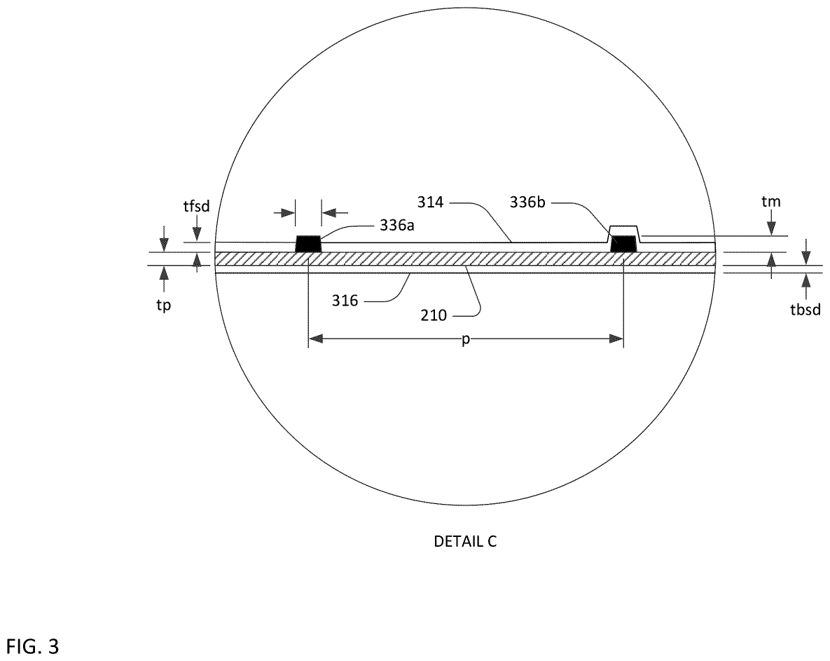

FIG. 3 shows a detailed schematic cross-sectional view of the XBAR 200. The piezoelectric plate 210 is a single-crystal layer of piezoelectric material having a thickness tp. tp may be, for example, 100 nm to 1500 nm. When used in filters for 5G NR and Wi-Fi bands from 3.3 GHZ to 7 GHz, the thickness tp may be, for example, 250 nm to 700 nm.

A front-side dielectric layer 314 may be formed on the front side of the piezoelectric plate 210. The “front side” of the XBAR is the surface facing away from the substrate. The front-side dielectric layer 314 has a thickness tfsd. The front-side dielectric layer 314 may be formed only between the IDT fingers (see IDT finger 336a). The front side dielectric layer 314 may also be deposited over the IDT fingers (see IDT finger 336b). A back-side dielectric layer 316 may be formed on the back side of the piezoelectric plate 210. The back-side dielectric layer 316 has a thickness tbsd. The front-side and back-side dielectric layers 314, 316 may be a non-piezoelectric dielectric material, such as silicon dioxide or silicon nitride. tfsd and tbsd may be, for example, 0 to 500 nm. Thicknesses tfsd and tbsd are each typically less than one-half of the thickness tp of the piezoelectric plate. Thicknesses tfsd and tbsd are not necessarily equal, and the front-side and back-side dielectric layers 314, 316 are not necessarily the same material. Either or both of the front-side and back-side dielectric layers 314, 316 may be formed of multiple layers of two or more materials.

The IDT fingers 336a, 336b may be one or more layers of aluminum, a substantially aluminum alloys, copper, a substantially copper alloys, beryllium, gold, molybdenum, or some other conductive material. Thin (relative to the total thickness of the conductors) layers of other metals, such as chromium or titanium, may be formed under and/or over the fingers to improve adhesion between the fingers and the piezoelectric plate 210 and/or to passivate or encapsulate the fingers. The busbars (232, 234 in FIG. 2) of the IDT may be made of the same or different materials as the fingers. As shown in FIG. 3, the IDT fingers 336a, 336b have rectangular or trapezoidal cross-sections. The IDT fingers may have some other cross-sectional shape.

Dimension p is the center-to-center spacing or “pitch” of the IDT fingers, which may be referred to as the pitch of the IDT and/or the pitch of the XBAR. Dimension w is the width or “mark” of the IDT fingers. The IDT of an XBAR differs substantially from the IDTs used in surface acoustic wave (SAW) resonators. In a SAW resonator, the pitch of the IDT is one-half of the acoustic wavelength at the resonance frequency. Additionally, the mark-to-pitch ratio of a SAW resonator IDT is typically close to 0.5 (i.e., the mark or finger width is about one-fourth of the acoustic wavelength at resonance). In an XBAR, the pitch p of the IDT is typically 2 to 20 times the width w of the fingers. In addition, the pitch p of the IDT is typically 2 to 20 times the thickness tp of the piezoelectric plate 210. The width of the IDT fingers in an XBAR is not constrained to one-fourth of the acoustic wavelength at resonance. For example, the width of XBAR IDT fingers may be 500 nm or greater, such that the IDT can be fabricated using optical lithography. The thickness tm of the IDT fingers may be from 100 nm to about equal to the width w. The thickness of the busbars (232, 234 in FIG. 2) of the IDT may be the same as, or greater than, the thickness tm of the IDT fingers.

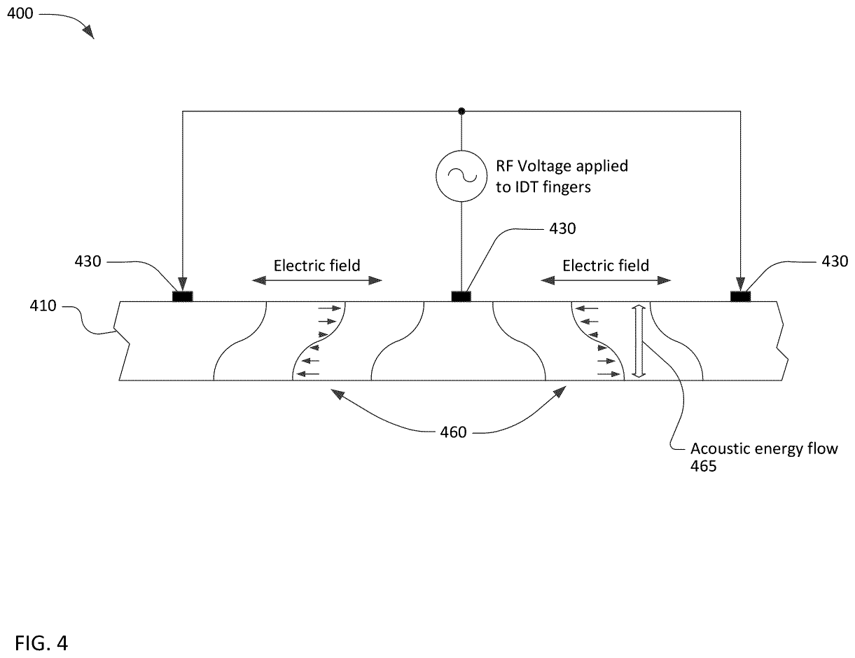

FIG. 4 is a graphical illustration of the primary acoustic mode of interest in an XBAR. FIG. 4 shows a small portion of an XBAR 400 including a piezoelectric plate 410 and three interleaved IDT fingers 430 (e.g., see IDT fingers 336a/b and/or fingers 236). A radio frequency (RF) voltage is applied to the interleaved fingers 430. This voltage creates a time-varying electric field between the fingers. The direction of the electric field is primarily lateral, or parallel to the surface of the piezoelectric plate 410, as indicated by the arrows labeled “electric field”. Since the dielectric constant of the piezoelectric plate is significantly higher than the surrounding air, the electric field is highly concentrated in the plate relative to the air. The lateral electric field introduces shear deformation, and thus strongly excites a shear-mode acoustic mode, in the piezoelectric plate 410. Shear deformation is deformation in which parallel planes in a material remain parallel and maintain a constant distance while translating relative to each other. A “shear acoustic mode” is an acoustic vibration mode in a medium that results in shear deformation of the medium. The shear deformations in the XBAR 400 are represented by the curves 460, with the adjacent small arrows providing a schematic indication of the direction and magnitude of atomic motion. The degree of atomic motion, as well as the thickness of the piezoelectric plate 410, have been greatly exaggerated for ease of visualization. While the atomic motions are predominantly lateral (i.e. horizontal as shown in FIG. 4), the direction of acoustic energy flow of the excited primary shear acoustic mode is substantially orthogonal to the surface of the piezoelectric plate, as indicated by the arrow 465.

An acoustic resonator based on shear acoustic wave resonances can achieve better performance than current state-of-the art film-bulk-acoustic-resonators (FBAR) and solidly-mounted-resonator bulk-acoustic-wave (SMR BAW) devices where the electric field is applied in the thickness direction. In such devices, the acoustic mode is compressive with atomic motions and the direction of acoustic energy flow in the thickness direction. In addition, the piezoelectric coupling for shear wave XBAR resonances can be high (>20%) compared to other acoustic resonators. High piezoelectric coupling enables the design and implementation of microwave and millimeter-wave filters with appreciable bandwidth.

The resonance frequency of an XBAR is determined by the thickness of the diaphragm and the pitch and mark (width) of the IDT fingers. The thickness of the diaphragm, which includes the thickness of the piezoelectric plate and the thicknesses of front-side and/or back-side dielectric layers, is the dominant factor determining the resonance frequency. The tuning range provided by varying the pitch and/or mark is limited to only a few percent. For broad bandwidth filters such as band-pass filter for 5G NR bands n77 and n79, 5 GHz Wi-Fi and 6 GHz Wi-Fi, the tuning range provided by varying the IDT pitch and finger width is insufficient to provide the necessary separation between the resonance frequencies of the shunt and the anti-resonance frequencies of the series resonators.

U.S. Pat. No. 10,491,192 describes the use of a front-side dielectric frequency setting layer formed only over shunt resonators to extend the bandwidth capability of XBAR filters. The dielectric frequency setting layer increases the thickness of the diaphragms of the shunt resonators and thus reduces the resonance frequency of the shunt resonators relative to the series resonators which decreases the frequency of the lower edge of the filter passband. However, there is a practical limit to the thickness of a frequency setting layer because a thick dielectric layer fosters additional spurious modes that may degrade filter performance.

U.S. Pat. No. 10,917,072 describes filters with series resonators and shunt resonators on different chips with different piezoelectric plate thicknesses. The piezoelectric plate of the chip with the shunt resonators is thicker than the piezoelectric plate of the chip with the series resonators. Thus, the resonance frequencies of the shunt resonators are lower than the resonance frequencies of the series resonators.

U.S. Pat. No. 11,201,601 describes filters with series resonators and shunt resonators with different piezoelectric plate thicknesses on a single chip. The piezoelectric plate of the shunt resonators is thicker than the piezoelectric plate of the series resonators. Thus, the resonance frequencies of the shunt resonators are lower than the resonance frequencies of the series resonators.

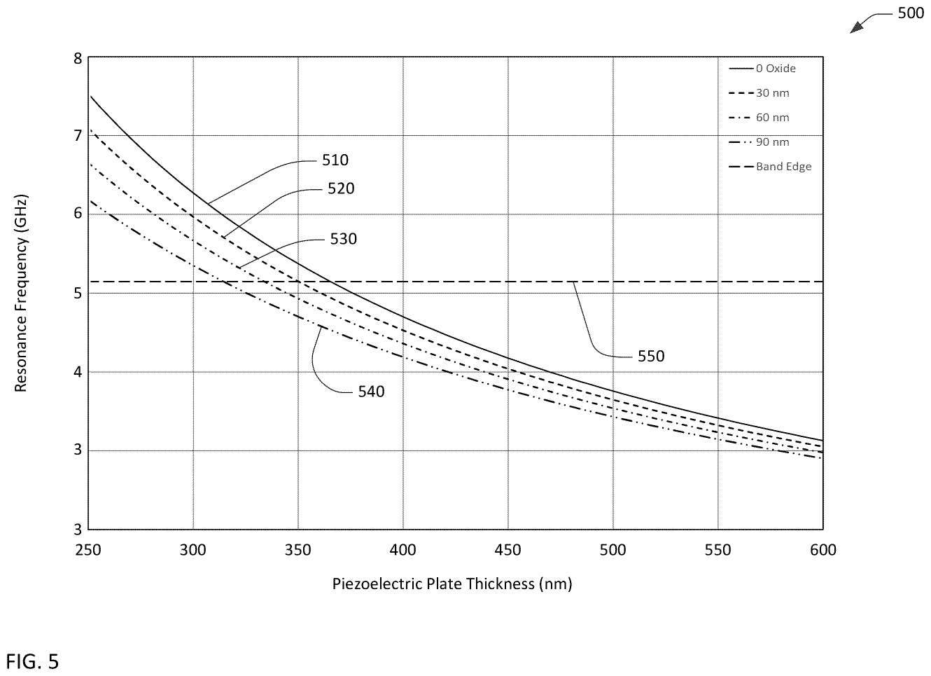

FIG. 5 is graph 500 of the relationship between the resonance frequency, piezoelectric plate thickness, and top-side dielectric thickness for representative XBARs using lithium niobate piezoelectric plates with Euler angles of [0°, 0°, 90°]. Such plates are commonly referred to as “Z-cut”.

The solid line 510 is a plot of the dependence of resonance frequency on piezoelectric plate thickness without a front-side dielectric layer. The short-dash line 520 is a plot of the dependence of resonance frequency on piezoelectric plate thickness with a front-side dielectric layer thickness of 30 nm. The dot-dash line 530 is a plot of the dependence of resonance frequency on piezoelectric plate thickness with a front-side dielectric layer thickness of 60 nm. The dot-dot-dash line 540 is a plot of the dependence of resonance frequency on piezoelectric plate thickness with a front-side dielectric layer thickness of 90 nm. In all cases, the piezoelectric plate is Z-cut lithium niobate, the IDT pitch is 10 times the piezoelectric plate thickness, the mark/pitch ratio is 0.25, and the IDT electrodes are aluminum with a thickness of 1.25 times the piezoelectric plate thickness. The dielectric layers are SiO₂. There is no back-side dielectric layer.

The long-dash line 550 marks the lower edge of the 5 GHz Wi-Fi bands at 5.15 GHz.

As previously described, in a ladder filter circuit, shunt resonators provide transmission zeros at frequencies below the lower edge of the filter passband. To this end, the resonance frequencies of the shunt resonators of a filter for the 5 GHz Wi-Fi bands must be less than 5150 MHz. Exactly how much less than 5150 MHz depends on the filter specifications, the Q-factors of the shunt resonators, and allowances for manufacturing tolerances and temperature variations. Commonly, the resonance frequencies of shunt resonators are less than the lower band edge by at least 2% of the frequency of the lower band edge (103 MHz in this example).

From FIG. 5 it can also be seen that 90 mm layer of SiO₂ has the same effect on resonance frequency as roughly a 50 nm change in the thickness of the lithium niobate piezoelectric plate. The thicknesses of the lithium niobate piezoelectric plate and the front-side SiO₂ layer can be combined to provide an equivalent thickness of the XBAR diaphragm as follows:

$$teqr = tp + kr ( tfsd ) \qquad ( 1 )$$

where teqr is the “LN-equivalent” thickness (i.e. the thickness of lithium niobate having the same resonance frequency) of the diaphragm for shunt resonators. The thicknesses tp and tfsd are the thickness of the piezoelectric plate and front-side dielectric layer as previously defined, and kr is a constant that is proportionally constant for shunt resonators. kr depends on the material of the front-side dielectric layer. When the front-side dielectric layer is SiO₂, kr is approximately 0.54.

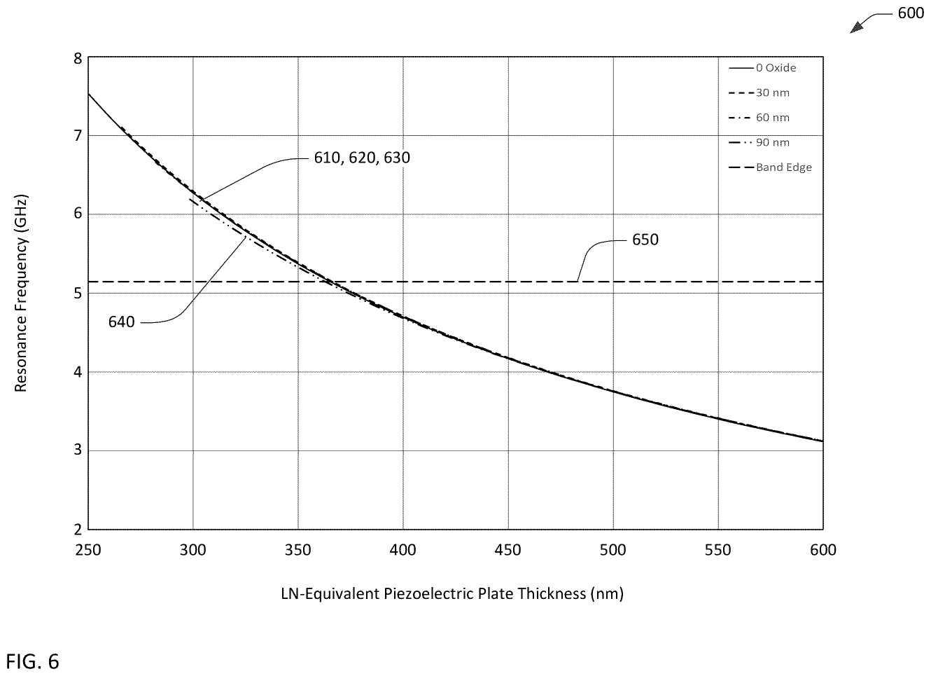

FIG. 6 is a graph 600 of the dependence of resonance frequency on LN-equivalent diaphragm thickness. The data shown in FIG. 6 is the same as the data shown in FIG. 5, with LN-equivalent thickness calculated using formula (1) with k=0.54. The solid line 610 is a plot of the dependence of resonance frequency on LN-equivalent piezoelectric plate thickness without a front-side dielectric layer. The short-dash line 620 is a plot of the dependence of resonance frequency on LN-equivalent piezoelectric plate thickness with a front-side dielectric layer thickness of 30 nm. The dot-dash line 630 is a plot of the dependence of resonance frequency on LN equivalent piezoelectric plate thickness with a front-side dielectric layer thickness of 60 nm. The dot-dot-dash line 640 is a plot of the dependence of resonance frequency on LN equivalent piezoelectric plate thickness with a front-side dielectric layer thickness of 90 nm. In all cases, the piezoelectric plate is Z-cut lithium niobate, the IDT pitch is 10 times the piezoelectric plate thickness, the mark/pitch ratio is 0.25, and the IDT electrodes are aluminum with a thickness of 1.25 times the piezoelectric plate thickness. The dielectric layers are SiO₂. There is no back-side dielectric layer.

The three curves 610, 620, 630 are substantially superimposed. The curve 640, representing the thickest dielectric layer, deviates from the other curves for thin piezoelectric plates.

The data in FIG. 6 is specific to XBARs with the IDT pitch equal to 10 times the piezoelectric plate thickness, a preferred range of the pitch of an XBAR is 6 to 12.5 times the IDT pitch (see U.S. Pat. No. 10,637,438). Electromechanical coupling decreases sharply for pitch less than 6 time the piezoelectric plate thickness, reducing the difference between the resonance and anti-resonance frequencies. Increasing the pitch above 12.5 times the piezoelectric plate thickness reduces capacitance per unit resonator area with little benefit in terms of electromechanical coupling or frequency change.

Reducing the pitch to 6 times the piezoelectric plate thickness increases resonance frequency by about 4.5% compared to an XBAR with pitch equal to 10 times the piezoelectric plate thickness. Increasing the pitch to 12.5 times the piezoelectric plate thickness reduces resonance frequency by about 1.1% compared to an XBAR with pitch equal to 10 times the piezoelectric plate thickness. An XBAR with pitch equal to 6 times the piezoelectric plate thickness will need a 4.5% thicker diaphragm to have the same resonance frequency as an XBAR with pitch equal to 10 times the piezoelectric plate thickness. An XBAR with pitch equal to 12.5 times the piezoelectric plate thickness will need a 1.1% thinner diaphragm to have the same resonance frequency as an XBAR with pitch equal to 10 times the piezoelectric plate thickness.

The long-dash horizontal line 650 represents the lower edges of the 5 GHz Wi-FI bands at 5.15 GHz. To ensure that the resonance frequencies of shunt resonators are lower than 5.15 GHZ, the LN-equivalent plate thickness must be greater than 365 nm. The LN-equivalent plate thickness would be reduced to about 360 nm if the pitch is increased to 12.5 time the piezoelectric plate thickness. In a filter for 5 GHz Wi-Fi bands, the diaphragms of all of the shunt resonators will have LN-equivalent thicknesses of greater than 360 nm. Typically, at least one shunt resonator will have a LN-equivalent diaphragm thickness of 365 nm to 375 nm to provide a transmission zero a at resonance frequency 50 MHz to 200 MHz less than the lower band edge (i.e. at 4.95 GHz to 5.10 GHz).

The LN-equivalent thickness of the diaphragm of the shunt resonators need not be the same. One or more additional dielectric layer may be formed over a subset of the shunt resonators to lower their resonance frequencies (for example to increase attenuation in a stop band below the lower band edge). While there is no absolute upper limit on the thickness of a front-side dielectric layer, XBARs with tfsd/tp>0.30 tend to have substantial spurious modes. Thus, a practical upper limit on LN-equivalent diaphragm thickness is about (1+0.3×0.54)(360 nm)=418 nm.

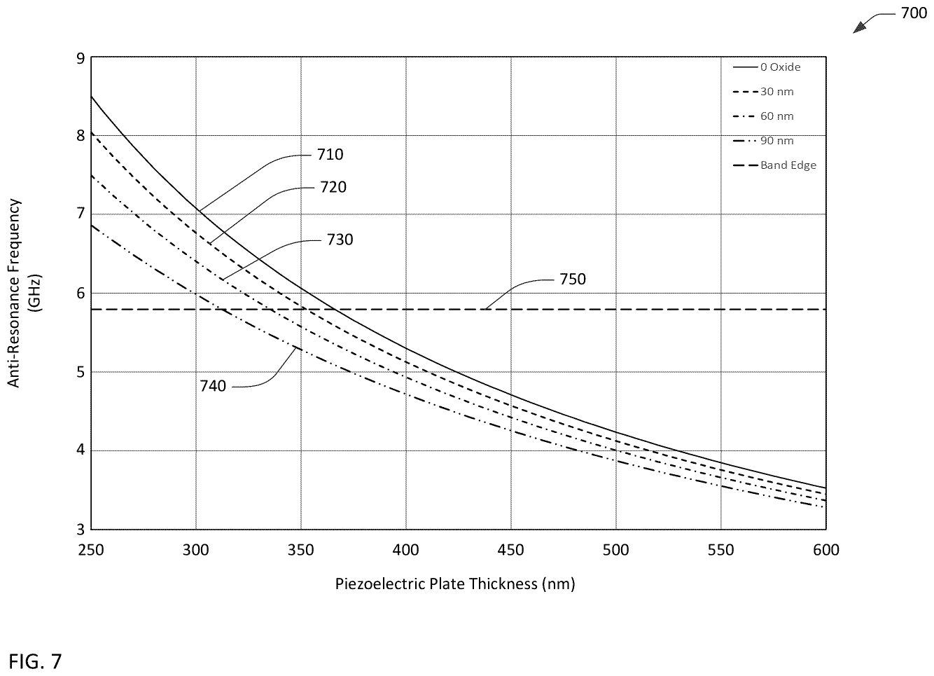

FIG. 7 is a graph 700 of the relationship between the anti-resonance frequency, piezoelectric plate thickness, and top-side dielectric thickness for representative XBARs. The solid line 710 is a plot of the dependence of anti-resonance frequency on piezoelectric plate thickness without a front-side dielectric layer. The short-dash line 720 is a plot of the dependence of anti-resonance frequency on piezoelectric plate thickness with a front-side dielectric layer thickness of 30 nm. The dot-dash line 730 is a plot of the dependence of anti-resonance frequency on piezoelectric plate thickness with a front-side dielectric layer thickness of 60 nm. The dot-dot-dash line 740 is a plot of the dependence of anti-resonance frequency on piezoelectric plate thickness with a front-side dielectric layer thickness of 90 nm. In all cases, the piezoelectric plate is Z-cut lithium niobate, the IDT pitch is 10 times the piezoelectric plate thickness, the mark/pitch ratio is 0.25, and the IDT electrodes are aluminum with a thickness of 1.25 times the piezoelectric plate thickness. The dielectric layers are SiO₂. There is no back-side dielectric layer.

The long-dash line 750 marks the upper edge of the 5 GHz Wi-Fi bands at 5.795 GHz. From FIG. 7, one can see that an anti-resonance frequency above 5.795 GHz can be obtained by different combinations of piezoelectric plate thickness and dielectric thickness. For example, with no dielectric layer, a piezoelectric plate thickness of about 365 nm results in an anti-resonance frequency of 5.795 GHz. Alternatively, a piezoelectric plate thickness of 312 nm with a 90 nm dielectric layer also provides an anti-resonance frequency of 5.795 GHz.

As previously described, in a ladder filter circuit, series resonators provide transmission zeros at frequencies above the upper edge of the filter passband. To this end, the anti-resonance frequencies of the series resonators of a filter for the 5 GHz Wi-Fi bands must be greater than 5.795 GHz. Exactly how much greater than 5.795 GHz depends on the filter specifications, the Q-factors of the series resonators, and allowances for manufacturing tolerances and temperature variations including temperature increases due to power consumed in the filter during transmission.

From FIG. 7 it can also be seen that a 90 mm layer of SiO₂ has the same effect on resonance frequency as roughly a 58 nm change in the thickness of the lithium niobate piezoelectric plate. The thicknesses of the lithium niobate piezoelectric plate and the front-side SiO₂ layer can be combined to provide an equivalent thickness of the XBAR diaphragm as follows:

$$teqa = tp + ka ( tfsd ) \qquad ( 1 )$$

where teqa is the “LN-equivalent” thickness (i.e. the thickness of lithium niobate having the same resonance frequency) of the diaphragm for series resonators. The thicknesses tp and tfsd are the thickness of the piezoelectric plate and front-side dielectric layer as previously defined, and ka is a constant that is a proportionally constant for series resonators. Constant ka depends on the material of the front-side dielectric layer. When the front-side dielectric layer is SiO₂, ka is approximately 0.52.

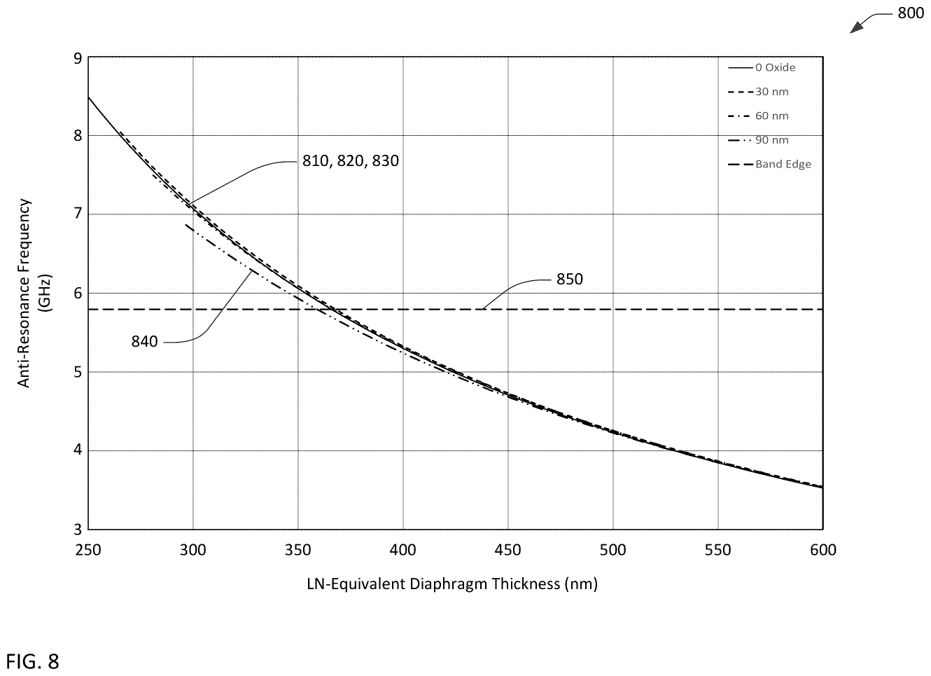

FIG. 8 is a graph 800 of the dependence of anti-resonance frequency on LN-equivalent diaphragm thickness. The data shown in FIG. 8 is the same as the data shown in FIG. 7, with LN-equivalent thickness calculated using formula (1) with ka=0.52. The solid line 810 is a plot of the dependence of anti-resonance frequency on LN-equivalent piezoelectric plate thickness without a front-side dielectric layer. The short-dash line 820 is a plot of the dependence of anti-resonance frequency on LN-equivalent piezoelectric plate thickness with a front-side dielectric layer thickness of 30 nm. The dot-dash line 830 is a plot of the dependence of anti-resonance frequency on LN-equivalent piezoelectric plate thickness with a front-side dielectric layer thickness of 60 nm. The dot-dot-dash line 840 is a plot of the dependence of anti-resonance frequency on LN-equivalent piezoelectric plate thickness with a front-side dielectric layer thickness of 90 nm. The lines 810, 820, 830 are nearly superimposed. The line 840, representing the thickest dielectric layer, deviates from the other curves for thin diaphragm thickness, possibly due to a reduction in the resonator coupling caused by the thick dielectric layer.

The long-dash horizontal line 850 marks the upper edge of the 5 GHz Wi-Fi bands are 5.795 GHz. An LN-equivalent thickness of 365 nm, which is the thickness that provides a resonance frequency of 3300 MHz for an XBAR with pitch equal to 10 times the piezoelectric plate thickness. Reducing the pitch to 6 times the piezoelectric plate thickness increases anti-resonance frequency by about 3.2% compared to an XBAR with pitch equal to 10 times the piezoelectric plate thickness. Conversely, an XBAR with pitch equal to 6 times the piezoelectric plate thickness will need a 3.2% thicker diaphragm to have the same anti-resonance frequency as an XBAR with pitch equal to 10 times the piezoelectric plate thickness. Assuming IDT pitch is not less than 6 times the piezoelectric plate thickness, the maximum LN-equivalent thickness for series resonators of a filter for the 5 GHz Wi-Fi bands is 365 nm×1.032 or about 375 nm.

In a filter for the 5 GHz Wi-Fi bands, the diaphragms of all of the series resonators will have LN-equivalent thicknesses less than 375 nm. While there is no absolute minimum diaphragms thickness, at least one series resonator in a typical filter for the 5 GHz Wi-Fi bands will have an LN-equivalent diaphragm thickness less than 365 nm and greater than 352 nm to provide an anti-resonance frequency 100 MHz to 300 MHz greater than the upper band edge.

The LN-equivalent thickness of the diaphragm of the series resonators need not be the same. One or more additional dielectric layer may be formed over a subset of the series resonators. The anti-resonance frequencies of series resonators without the additional dielectric layer will be further above the upper band edge (for example to increase attenuation in a stop band above the upper band edge).

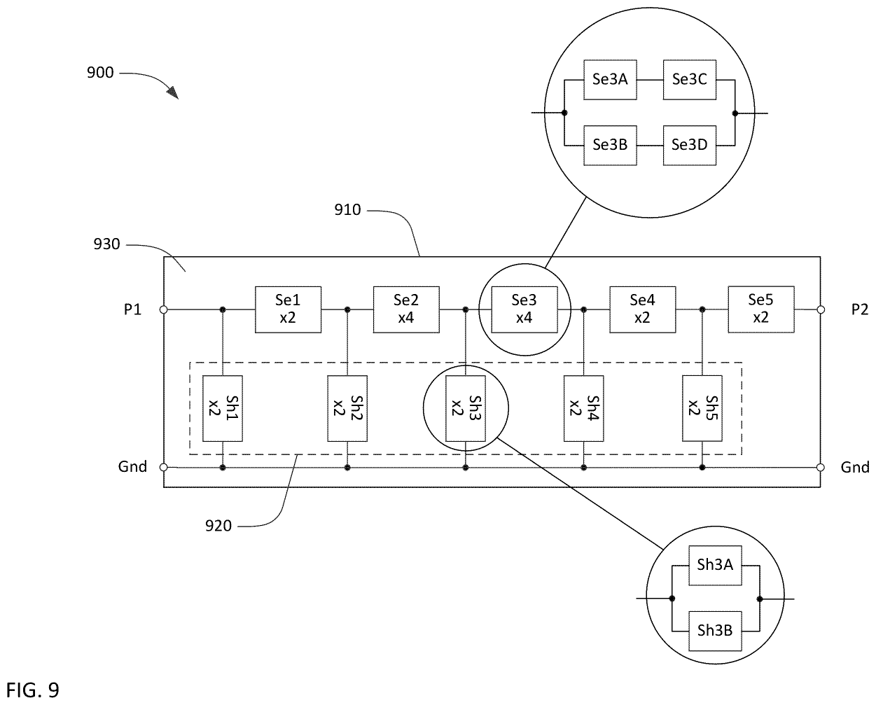

FIG. 9 is a schematic circuit diagram of an exemplary filter 900 for the 5 GHz Wi-Fi bands using five series resonators Se1, Se2, Se3, Se4, Se5 and five shunt resonators Sh1, Sh2, Sh3, Sh4, Sh5. The filter 900 has a conventional ladder filter architecture. The five series resonators Se1, Se2, Se3, Se4, Se5 are connected in series between a first port P1 and a second port P2. The filter 900 is bidirectional and either port may serve as the input or output of the filter. Shunt resonator Sh1 is connected from port P1 to ground. The other four shunt resonators Sh2, Sh3, Sh4, Sh5, are connected from nodes between the series resonators to ground. All the shunt resonators and series resonators are composed of multiple XBAR sub-resonators connected in parallel. The number of sub-resonators is indicated below the reference designator (e.g. “×4”) of each resonator, where ×4 represents four sub-resonators and ×2 represents two sub-resonators. Dividing an XBAR into multiple sub-resonators has a primary benefit of reducing the peak stress that would occur if each XBAR had a single large diaphragm. The multiple sub-resonators of each resonator typically, but not necessarily, have the same aperture and approximately the same length.

The pitch and mark of the sub-resonators comprising any of the series or shunt resonators are not necessarily the same. As shown in the detailed schematic diagram, series resonator Se3 is composed of four sub-resonators Se3A, Se3B, Se3C, Se3D. Pair of series sub-resonators Se3A, Se3C and pair of series sub-resonators Se3B, Se3D are connected in parallel. Each of the sub-resonators Se3A-Se3D has a unique mark and pitch, which is to say the mark and pitch of any sub-resonator is different from the mark and pitch of each other sub-resonator. Co-pending application Ser. No. 17/039,239, Transversely-Excited Film Bulk Acoustic Resonator with Multi-Pitch Interdigital Transducer, describes the use of small variations (e.g. +1%) in pitch within the IDT of an XBAR to reduce the amplitude of spurious modes. The small variations in pitch shift the frequencies of spurious modes such that the spurious modes do not add constructively over the area of the XBAR. These small pitch variations have a negligible effect on the resonance and anti-resonance frequencies. The small changes in pitch between the sub-resonators Se3A, Se3B, Se3C, Se3D have a similar effect. The spurious modes of the sub-resonators do not add, resulting in lower overall spurious mode amplitude. As shown in the detailed schematic diagram, shunt resonator Sh3 is composed of two sub-resonators Sh3A, Sh3B connected in parallel. Each of the sub-resonators Sh3A-Sh3B may have a unique mark and pitch so that the spurious modes of the sub-resonators do not add as noted for the series sub-resonators. This technique is used in three of the five shunt resonators of the filter 900.

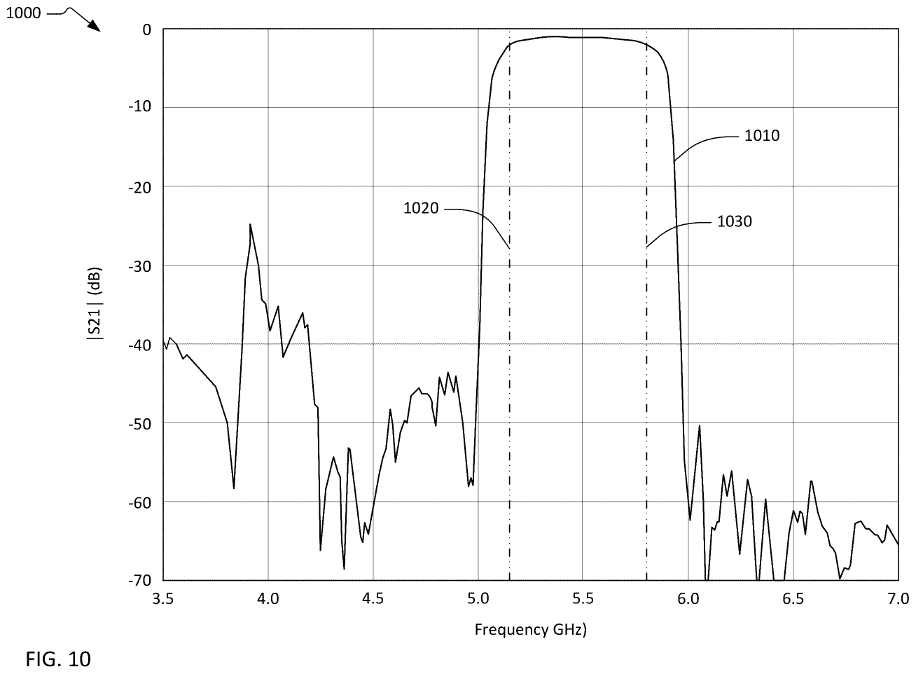

FIG. 10 is a graph 1000 of the performance of an exemplary filter for the 5 GHz Wi-Fi bands, which may be, or be similar to, the filter 900 of FIG. 9. Specifically, the curve 1010 is a plot of the magnitude of the input/output transfer function S21 of the exemplary filter over a frequency range from 100 MHZ to 10 GHz. The dot-dot-dash lines 1020 and 1030 mark the lower and upper edges the 5 GHz Wi-Fi bands, respectively. By selecting desired LN-equivalent thickness (e.g., plate thickness and front side dielectric thickness) as noted in FIGS. 5-8, it is possible to accomplish the desired 5 GHz Wi-Fi bands of FIG. 10. Selecting desired pitch and mark as noted for FIG. 9 can also assist in accomplishing the desired 5 GHz Wi-Fi bands of FIG. 10.

### Description of Methods

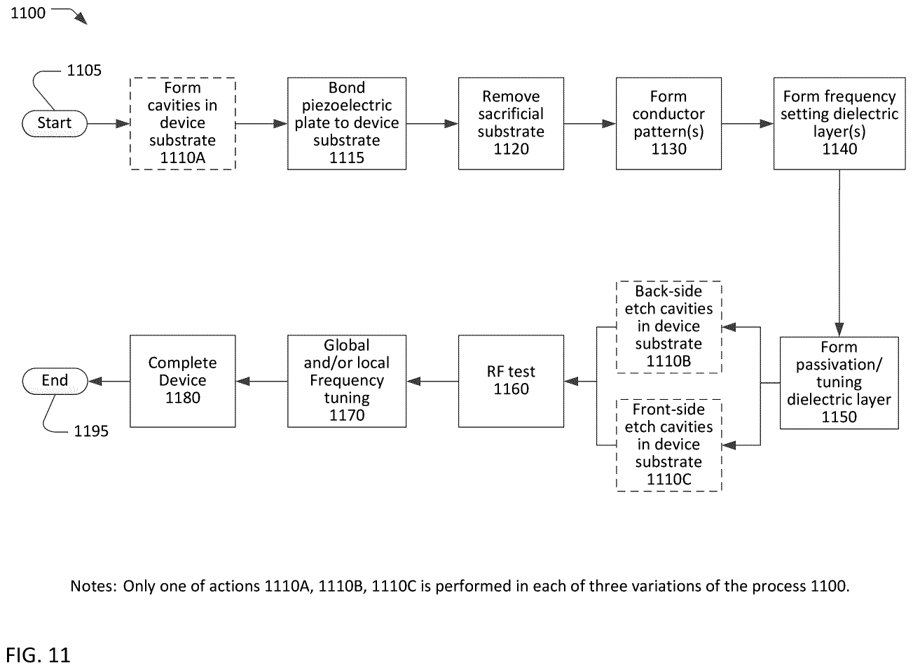

FIG. 11 is a simplified flow chart showing a process 1100 for making a wafer with a plurality of chips containing XBARs. The process 1100 starts at 1105 with a device substrate and a plate of piezoelectric material attached to a sacrificial substrate. The process 1100 ends at 1195 with a plurality of completed XBAR chips, such as those of filter 900. The flow chart of FIG. 11 includes only major process steps. Various conventional process steps (e.g. surface preparation, cleaning, inspection, baking, annealing, monitoring, testing, etc.) may be performed before, between, after, and during the steps shown in FIG. 11. With the exception of step 1180, all of the actions are performed concurrently on all chips on the wafer.

The flow chart of FIG. 11 captures three variations of the process 1100 for making an XBAR which differ in when and how cavities are formed in the device substrate. The cavities may be formed at steps 1110A, 1110B, or 1110C. Only one of these steps is performed in each of the three variations of the process 1100.

The piezoelectric plate may be, for example, rotated YX-cut lithium niobate. The piezoelectric plate may be some other material and/or some other cut. The substrate may preferably be silicon. The substrate may be some other material that allows formation of deep cavities by etching or other processing.

In one variation of the process 1100, one or more cavities are formed in the device substrate at 1110A before the piezoelectric plate is bonded to the substrate at 1115. A separate cavity may be formed for each resonator on the chip. The one or more cavities may be formed using conventional photolithographic and etching techniques. Typically, the cavities formed at 1110A will not penetrate through the device substrate.

At 1115, the piezoelectric plate is bonded to the device substrate. The piezoelectric plate and the substrate may be bonded by a wafer bonding process. Typically, the mating surfaces of the substrate and the piezoelectric plate are highly polished. One or more layers of intermediate materials, such as an oxide or metal, may be formed or deposited on the mating surface of one or both of the piezoelectric plate and the substrate. One or both mating surfaces may be activated using, for example, a plasma process. The mating surfaces may then be pressed together with considerable force to establish molecular bonds between the piezoelectric plate and the substrate or intermediate material layers.

The sacrificial substrate may be removed at 1120, exposing a front surface of the piezoelectric plate. The actions at 1120 may include further processes, such as polishing and/or annealing, to prepare the exposed surface for subsequent process steps.

A conductor pattern, including IDTs of each XBAR, is formed at 1130 by depositing and patterning one or more conductor layers on the front surface of the piezoelectric plate. The conductor layer may be, for example, aluminum or an aluminum alloy with a thickness of 50 nm to 150 nm. Optionally, one or more layers of other materials may be disposed below (i.e. between the conductor layer and the piezoelectric plate) and/or on top of the conductor layer. For example, a thin film of titanium, chrome, or other metal may be used to improve the adhesion between the conductor layer and the piezoelectric plate. A conduction enhancement layer of gold, aluminum, copper or other higher conductivity metal may be formed over portions of the conductor pattern (for example the IDT busbars and interconnections between the IDTs).

The conductor pattern may be formed at 1130 by depositing the conductor layer and, optionally, one or more other metal layers in sequence over the surface of the piezoelectric plate. The excess metal may then be removed by etching through patterned photoresist. The conductor layer can be etched, for example, by plasma etching, reactive ion etching, wet chemical etching, and other etching techniques.

Alternatively, the conductor pattern may be formed at 1130 using a lift-off process. Photoresist may be deposited over the piezoelectric plate, and patterned to define the conductor pattern. The conductor layer and, optionally, one or more other layers may be deposited in sequence over the surface of the piezoelectric plate. The photoresist may then be removed, which removes the excess material, leaving the conductor pattern.

One or more optional frequency setting dielectric layers may be formed at 1140 by depositing and patterning one or more dielectric layers on the front surface of the piezoelectric plate. The dielectric layer(s) may be formed between, and optionally over, the IDT fingers of some, but not all XBARs. The frequency setting dielectric layer(s) are typically SiO₂, but may be Si₃N₄, Al₂O₃, or some other dielectric material. The thickness of each frequency setting dielectric layer is determined by the desire frequency shift. In the example of FIG. 9 and FIG. 10, a frequency setting dielectric layer 80 nm thick is formed over the IDTs of the five shunt resonators.

A passivation/tuning dielectric layer is formed at 1150 by depositing a dielectric material over all of the front surface of the piezoelectric plate except pads used for electric connections to circuitry external to the chip. The passivation/tuning layer may be SiO₂, Si₃N₄, Al₂O₃, some other dielectric material, or a combination of two or more materials. The thickness of passivation/tuning layer is determined by the minimum amount of dielectric material required to deal the surface of the chip plus the amount of sacrificial material possibly needed for frequency tuning at 1170. In the example of FIG. 9 and FIG. 10, a passivation/tuning layer 20 nm thick (after tuning) may be assumed over the IDTs of all XBARs.

In a second variation of the process 1100, one or more cavities are formed in the back side of the substrate at 1110B. A separate cavity may be formed for each resonator on the chip. The one or more cavities may be formed using an anisotropic or orientation-dependent dry or wet etch to open holes through the back side of the substrate to the piezoelectric plate.

In a third variation of the process 1100, one or more cavities in the form of recesses in the substrate may be formed at 1110C by etching the substrate using an etchant introduced through openings in the piezoelectric plate. A separate cavity may be formed for each resonator in a filter device. The one or more cavities formed at 1110C will not penetrate through the substrate.

In all variations of the process 1100, some or all of XBARs on each chip may be measured or tested at 1160. For example, the admittance of some or all XBARs may be measured at RF frequencies to determine the resonance and/or the anti-resonance frequencies. The measured frequencies may be compared to the intended frequencies and a map of frequency errors over the surface of the wafer may be prepared.

At 1170, the frequency of some or all XBARs may be tuned by selectively removing material from the surface of the passivation/tuning layer in accordance with the frequency error map developed at 1160. The selective material removal may be done, for example, using a scanning ion mill or other tool.

In some cases, the piezoelectric plate is Z-cut lithium niobate, the IDT pitch is 10 times the piezoelectric plate thickness, the mark/pitch ratio is 0.25, and the IDT electrodes are aluminum with a thickness of 1.25 times the piezoelectric plate thickness. The frontside dielectric layers are SiO₂ and have a thickness of 0, 30, 60 or 90 nm. There is no back-side dielectric layer.

The chips may then be completed at 1180. Actions that may occur at 1180 include forming bonding pads or solder bumps or other means for making connection between the chips and external circuitry, additional testing, and excising individual chips from the wafer containing multiple chips. After the chips are completed, the process 1100 ends at 1195.

### CLOSING COMMENTS

Throughout this description, the embodiments and examples shown should be considered as exemplars, rather than limitations on the apparatus and procedures disclosed or claimed. Although many of the examples presented herein involve specific combinations of method acts or system elements, it should be understood that those acts and those elements may be combined in other ways to accomplish the same objectives. With regard to flowcharts, additional and fewer steps may be taken, and the steps as shown may be combined or further refined to achieve the methods described herein. Acts, elements and features discussed only in connection with one embodiment are not intended to be excluded from a similar role in other embodiments.

As used herein, “plurality” means two or more. As used herein, a “set” of items may include one or more of such items. As used herein, whether in the written description or the claims, the terms “comprising”, “including”, “carrying”, “having”, “containing”, “involving”, and the like are to be understood to be open-ended, i.e., to mean including but not limited to. Only the transitional phrases “consisting of” and “consisting essentially of”, respectively, are closed or semi-closed transitional phrases with respect to claims. Use of ordinal terms such as “first”, “second”, “third”, etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements. As used herein, “and/or” means that the listed items are alternatives, but the alternatives also include any combination of the listed items.

It is claimed:

1. A bandpass filter comprising:
a ladder filter circuit comprising a shunt bulk acoustic resonator and a series bulk acoustic resonator,
wherein the series bulk acoustic resonator comprises:
a lithium niobate (LN) layer;
a dielectric layer on the series bulk acoustic resonator,
wherein the series bulk acoustic resonator has an LN-equivalent thickness less than or equal to 375 nanometers, and the LN-equivalent thickness of the series bulk acoustic resonator is given by:
$$teqa = tp + ka ( tfsd )$$
where teqa is the LN-equivalent thickness of the series bulk acoustic resonator, tp is the thickness of the LN layer of the series bulk acoustic resonator, ka is a proportionality constant for the series bulk acoustic resonator and ka=0.52, and tfsd is a thickness of the dielectric layer on the series bulk acoustic resonator.

2. The bandpass filter of claim 1, wherein the shunt bulk acoustic resonator comprises:
an LN layer;
a dielectric layer on the shunt bulk acoustic resonator,
wherein the shunt bulk acoustic resonator has an LN-equivalent thickness greater than or equal to 360 nanometers, and the LN-equivalent thickness of the shunt bulk acoustic resonator is given by teqr:
$$teqr = tp + kr ( tfsd )$$
where tp is the thickness of the LN layer of the shunt bulk acoustic resonator, and kr is a proportionality constant for the shunt bulk acoustic resonator where kr=0.54, and tfsd is a thickness of the dielectric layer of the shunt bulk acoustic resonator on the shunt bulk acoustic resonator.

3. The bandpass filter of claim 2, wherein the shunt bulk acoustic resonator comprises a diaphragm having an LN-equivalent thickness greater than or equal to 370 nm.

4. The bandpass filter of claim 1, wherein the series bulk acoustic resonator has an LN-equivalent thickness less than or equal to 365 nm.

5. The bandpass filter of claim 1, wherein the LN layer of the series bulk acoustic resonator has a thickness less than or equal to the thickness of the LN layer of the series bulk acoustic resonator.

6. The bandpass filter of claim 1, wherein the LN layer has Euler angles [0°, 0°, 90°].

7. The bandpass filter of claim 1, wherein the shunt bulk acoustic resonator is on a first chip and the series bulk acoustic resonator is on a second chip.

8. The bandpass filter of claim 7, wherein the first chip of the shunt bulk acoustic resonator is electrically connected to the second chip of the series bulk acoustic resonator in a ladder filter circuit.

9. The bandpass filter of claim 1, wherein the shunt bulk acoustic resonator is one of a plurality of shunt bulk acoustic resonators in the bandpass filter, and the series bulk acoustic resonator is one of a plurality of series bulk acoustic resonators in the bandpass filter, and wherein the LN-equivalent thickness of any one of the shunt resonators is more than the LN-equivalent thickness of any one of the series resonators.

10. The bandpass filter of claim 1, wherein the dielectric layer on the series bulk acoustic resonator is silicon oxide and the dielectric layer on the shunt bulk acoustic resonator is silicon oxide.

11. The bandpass filter of claim 1, wherein the shunt bulk acoustic resonator is composed of a plurality of sub-resonators, that are a same length as each other.

12. The bandpass filter of claim 11, wherein the sub-resonators are connected in parallel to each other.

13. The bandpass filter of claim 11, wherein the sub-resonators are connected in series to each other.

14. The bandpass filter of claim 1, wherein the series bulk acoustic resonator is composed of a plurality of sub-resonators that are a same length as each other.

15. The bandpass filter of claim 14, wherein the plurality of sub-resonators are connected in parallel to each other.

16. The bandpass filter of claim 1, wherein the series bulk acoustic resonator further comprises an interdigitated transducer having interleaved fingers, and the shunt bulk acoustic resonator further comprises an interdigital transducer having interleaved fingers.

17. The bandpass filter of claim 16, wherein a pitch of the series bulk acoustic resonator is a center-to-center distance between two adjacent interleaved fingers of the series bulk acoustic resonator, the pitch of the shunt bulk acoustic resonator is a center-to-center distance between two adjacent interleaved fingers of the shunt bulk acoustic resonator, and the pitch of the series bulk acoustic resonator is different than the pitch of the shunt bulk acoustic resonator.

18. The bandpass filter of claim 16, wherein a pitch of the series bulk acoustic resonator is a center-to-center distance between two adjacent interleaved fingers of the series bulk acoustic resonator and a mark of the series bulk acoustic resonator is a width of one of the interleaved fingers of the series bulk acoustic resonator, the pitch of the shunt bulk acoustic resonator is a center-to-center distance between two adjacent interleaved fingers of the shunt bulk acoustic resonator and a mark of the shunt bulk acoustic resonator is a width of one of the interleaved fingers of the shunt bulk acoustic resonator, and wherein the pitch of each of the series and shunt bulk acoustic resonators is between 2 and 20 times the mark.

19. A bandpass filter comprising:
a series bulk acoustic wave resonator and a shunt bulk acoustic wave resonator in a ladder filter circuit, wherein each of the series and shunt bulk acoustic wave resonators comprises:
a substrate;
a lithium niobate (LN) layer bonded to the substrate by one or more intermediate oxide layers, the lithium niobate layer over a cavity;
a conductor pattern comprising an interdigital transducer on the LN layer; and
a dielectric layer over the interdigital transducer and between the interdigital transducer on the LN layer, and
wherein the LN layer and the dielectric layer of the series bulk acoustic wave resonator has an LN-equivalent thickness less than or equal to 375 nanometers, the LN-equivalent thickness of the series bulk acoustic resonator is given by:
$$teqa = tp + ka ( tfsd )$$
where teqa is the LN-equivalent thickness of the LN layer series bulk acoustic resonator, tp is the thickness of the LN layer of the series bulk acoustic resonator, ka is a proportionality constant for the series bulk acoustic resonator and ka=0.52, and tfsd is a thickness of the dielectric layer.

20. The bandpass filter of claim 19, wherein the shunt bulk acoustic resonator has an LN-equivalent thickness greater than or equal to 360 nanometers, and the LN-equivalent thickness of the shunt bulk acoustic resonator is given by teqr:
teqr=tp+kr(tfsd)
where tp is the thickness of the LN layer of the shunt bulk acoustic resonator, and kr is a proportionality constant for the shunt bulk acoustic resonator where kr=0.54, and tfsd is a thickness of the dielectric layer of the shunt bulk acoustic resonator on the shunt bulk acoustic resonator.
